(19) United States
(12) Patent Application Publication
(10) Pub. No.: US 2008/0191318 A1
(43) Pub. Date: Aug. 14, 2008

(54) SEMICONDUCTOR DEVICE AND METHOD OF SAWING SEMICONDUCTOR DEVICE

(75) Inventors: Michael Zhuoying Su, Round Rock, TX (US); Lei Fu, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: ADVANCED MICRO DEVICES, INC., Sunnyvale, CA (US)

(21) Appl. No.: 11/673,235

(22) Filed: Feb. 9, 2007

(51) Int. Cl. H01L 21/00; H01L 23/00

(52) U.S. Cl. 257/620; 438/462; 257/E23.001; 257/E21.001

(57) ABSTRACT

A method is disclosed for singulating die containing semiconductor device whereby a trench is etched at a first scribe region of a wafer comprising semiconductor devices, and sawing the wafer within the trench.

### FIELD OF THE DISCLOSURE

The present disclosure relates to manufacturing of integrated circuit devices, and more particularly to sawing of wafers at which integrated circuit devices are formed.

### DESCRIPTION OF THE RELATED ART

Sawing of wafers containing dice having integrated circuits is the first step in the packaging of integrated circuits and can have a significant impact on device yields and reliability. One aspect of sawing that affects yield and reliability is that dielectric materials at the dice have a tendency to delaminate, chip and crack when exposed to sawing processes, especially when using low-k dielectric materials which possesses relatively lower mechanical properties of hardness, modulus, fracture toughness, and poor adhesion. In addition to yield and reliability issues, blades used, such as diamond tipped blades, to saw semiconductor wafers can be costly and need to be replaced with relative frequency. In some instances, a different blade is needed to cut a wafer in a horizontal direction than is needed to cut the wafer in a horizontal direction, thereby adding additional cost.

The use of lasers has been proposed to replace the use of blades to reduce mechanical stresses that can cause cracking and other failures that occur during sawing. However, lasers are not always effective on transparent materials and can create large heat differentials that cause chipping, cracking, delamination, and the formation of brittle recast debris of the dielectric materials at the dice. In addition, the use of lasers can be relatively slow as compared to sawing techniques that use blades.

The use of lasers in combination with blades or water jets has been proposed whereby a short-pulse laser beam is used to create two grooves through dielectric layers on the edge of a scribe region, followed by the use of a traditional saw to cut between the grooves and through the wafer. The use of lasers continues to be problematic as described above, in addition the requirement of using multiple tools and machines increases processing time and costs. However, the heat of the laser can still affect the reliability of the devices. Therefore, a method and apparatus overcoming these problems would be useful.

### SUMMARY

### BRIEF DESCRIPTION OF THE DRAWINGS

The present disclosure may be better understood, and its numerous features and advantages made apparent to those skilled in the art by referencing the accompanying drawings.

FIG. 1 includes an illustration of a plan top view of a semiconductor wafer workpiece;

FIG. 2 includes an illustration of a cross-sectional view of a portion of the workpiece of FIG. 1;

FIG. 3 is a detailed representation of a cross-sectional view of a portion of a workpiece;

FIG. 4 includes an illustration of the workpiece of FIG. 4 after formation of a mask opening during patterning;

FIG. 5 includes an illustration of the workpiece of FIG. 5 after formation of a trench;

FIGS. 6-8 includes an illustrations of the workpiece of FIG. 6 being sawed;

FIG. 9 includes an illustration of a portion of the workpiece after sawing;

FIG. 10 is a plan view of a workpiece illustrating scribe, trench, and saw cut regions in accordance with the present disclosure.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

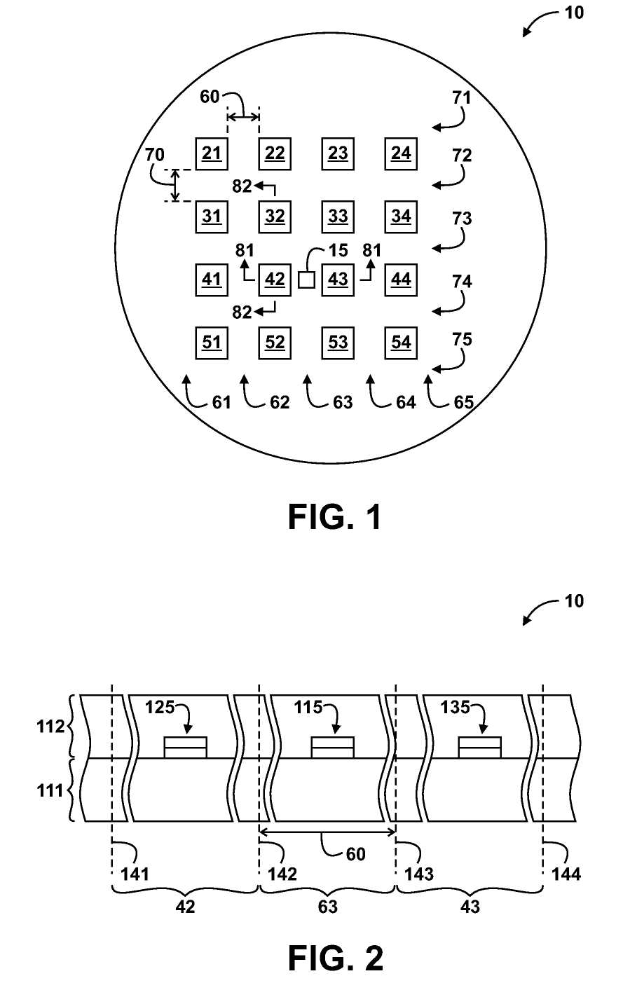

In accordance with a specific embodiment of the present disclosure an etch process is used in conjunction with a dicing saw to cut wafers during a die singulation. An etch is used prior to sawing to etch a trench at scribe regions of a wafer. Subsequent to forming the trench, a saw can cut through the wafer within the trench. In this manner, the active layers of the integrated circuit, such as the dielectric layers, are not exposed to the stresses of sawing, thus, avoided cracking and delamination in the die area, thereby improving yield and reliability. The present disclosure will be better understood with reference to FIGS. 1-10 described below.

FIG. 1 illustrates a plan view of a workpiece 10, which is a semiconductor wafer. A plurality of die locations at workpiece 10 is identified by reference number 21-24, 31-34, 41-44, and 51-53. Scribe lines are adjacent to the dice rows and columns and are represented by reference numbers 61-65 and 71-75. Each illustrated scribe line can be identified as a horizontal scribe lines or vertical scribe regions, with horizontal and vertical scribe lines being orthogonal to each other. For purposes of discussion, the scribe lines 61-65 are also referred to as vertical scribe lines, while the scribe lines 71-75 are referred to as horizontal scribe lines. The horizontal spacing of the vertical scribe region between die 21 and die 22, i.e., the width of vertical scribe line 62 is represented by a dimension 60, and can be the same for each vertical scribe line 61-65. The vertical spacing of the horizontal scribe region between die 21 and die 31, i.e., the width of vertical scribe line 72, is represented by a dimension 70, and can be the same for each horizontal scribe line 71-75. The dimension 60 and the dimension 70 can be the same or different. Reference numeral 81 represents a location of cross-sectional view as illustrated at FIG. 2. Reference numeral 82 represent the location of a cross-sectional view as illustrated at FIG. 8.

Also illustrated at FIG. 1 is a device location 15 identifying the location of a scribe region device that can be a test device, die seal, or other device formed at a scribe region of scribe line 63 to be used during the manufacturing of the workpiece 10. Note that a plurality of scribe region devices is typically formed at each scribe line, however only one such device is illustrated in FIG. 1.

FIG. 2 illustrates in cross-sectional view a portion of workpiece 10 in accordance with a specific embodiment of the disclosure at cross section view 81 (FIG. 1). Specifically illustrated at FIG. 2 is a substrate at level 111 and active layers at level 112. The term substrate as used herein is intended to refer to a semiconductor on insulator (SOI) substrate, a bulk semiconductor substrate, a sapphire substrate, and the like, at which structure used to form semiconductor devices can be formed. The term active layers as used herein is intended to refer to layers of level 112 that are formed in conjunction with the formation of semiconductor devices.

Level 112 is illustrated in FIG. 2 to include transistor gate structure 125 formed at die location 42, scribe region structure 115 at location 15, and transistor gate structure 135 formed at die location 43. Transistor gate structures 125 and 135 are illustrated to have an active layer that forms a gate dielectric layer, an active layer that forms a conductive gate layer, and an active layer that forms a dielectric region overlying the conductive gate. Structure 115 can be a transistor or other structure formed using the same, or different active layers as the transistor gate structure 123 or 135.

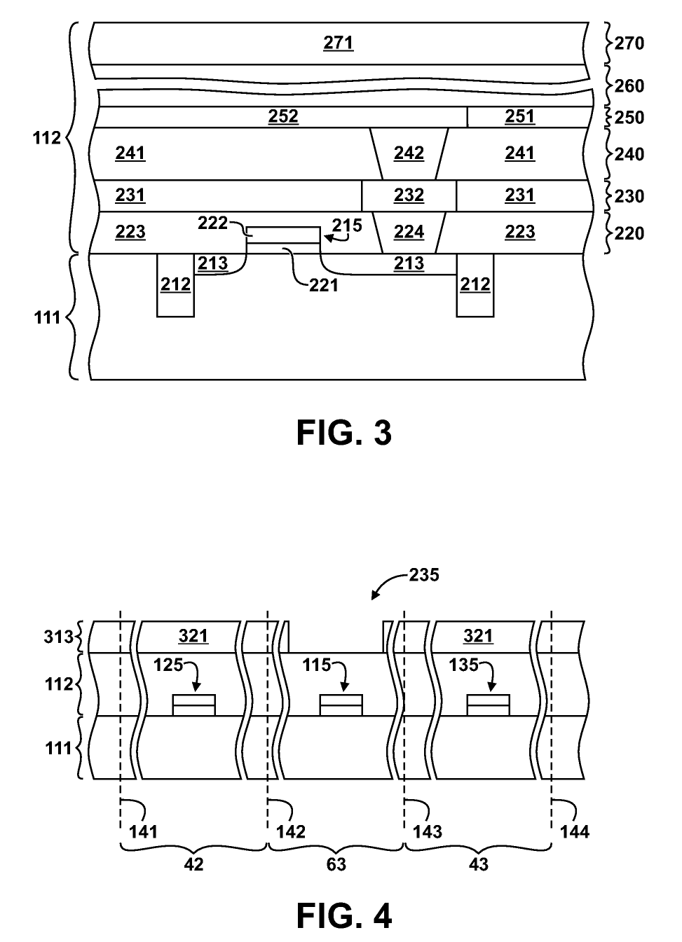

FIG. 3 illustrates a more detailed representation of a portion of workpiece 10 of FIG. 2 that can represent either a specific die location or scribe region. Within substrate level 111 isolation regions 212 and source/drain regions 213 have been formed. Level 112 is illustrated to include a plurality of levels at which one or more layers are formed. For example level 220 is illustrated to include portions of transistor 215 including a gate dielectric layer 221, conductive gate layer 222, dielectric layer 223, and conductive contact 224.

Level 230 represents an interconnect layer that is illustrated to include a conductive layer 232, also referred to as a conductive line 232, and a dielectric layer 231 formed from a dielectric material having, for example, a dielectric constant k≦3.6. Level 240 is a via layer that is illustrated to include a conductive layer 242 that is also referred to as a via 242, and dielectric layer 241 that is formed from a dielectric material. Note the via 242 is in contact with conductive line 232 of level 230. Level 250 represents an interconnect layer that is illustrated to include a conductive layer 232, also referred to as conductive line 252,and a dielectric layer 251 formed from a dielectric material. Level 260 represents additional via and interconnect levels. Level 270 represents a passivation layer 271, which can be formed, for example, from various polymides, at which openings to bond pads, and other conductive structures are formed.

It will be appreciated that in accordance with one embodiment, scribe regions can have some or all of the same levels and corresponding layers as regions associated with their adjacent die locations. It will also be appreciated that the layers associated with levels 230, 240, 250, 260, and 270 are generally referred to as BEOL (Back End of Line) layers, while layers used to form transistor 215 are generally referred to as FEOL (Front End of Line) layers.

FIG. 4 includes an illustration of workpiece 10 of FIG. 2 after a masking layer 321 has been formed overlying the active level 112. The patterning of masking layer 321 resulted in formation of an opening 235 that defines a location at which a trench region is to be formed at region of scribe region. The term “scribe region” is used herein to refer to all or some of a particular scribe line. The term “trench region” is used herein to refer to all or some of a trench formed at a scribe region. For example, the term “trench region” can refer to all or some of a trench formed at a scribe region that abuts both die location 32 and die location 42.

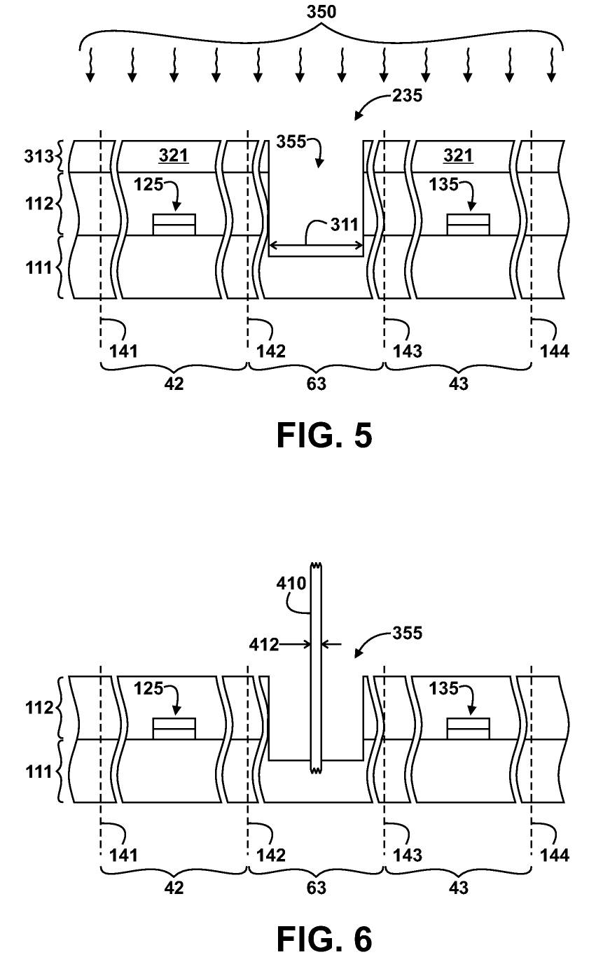

FIG. 5 includes an illustration of the formation of trench regions 355 as defined by opening 235 of workpiece 10 of FIG. 4. In accordance with a specific embodiment of the present disclosure, trench region 355 has been formed by an etch process 350 that etches through the materials at level 112 and level 111 leaving portions of these materials exposed at the openings in level 313. The etch process 350 can be an anisotropic etch or an isotropic etch. The etch process 350 can include a deep reactive ion etch (DRIE) or a wet chemical etch. DRIE processes are most frequently applied in high density, inductively coupled plasma (ICP) and low pressure (˜1 mTorr) etching systems. During a DRIE, a thin layer of CₓF_{y} polymer deposits on the wafer surface and the sidewall of the trench, at the same time that heavy ions bombard the surface. There are different mechanisms for DRIE of silicon and dielectric materials. For silicon, a Bosch Process can be applied, which comprises a sequence of alternating process steps of silicon etching and protective polymer deposition, each of a few seconds duration in a high density plasma, whereby each etching step provides a short period of high rate somewhat isotropic silicon removal. Each polymer deposition step generates a passivating polymer film that prevents lateral etching of the exposed silicon sidewalls during subsequent etching cycles. For low-k dielectric materials, the mechanism of etching is based on the continuous deposition of a thin polymer layer on the surface of the wafer, which at the same time is bombarded by heavy ions to generate a reaction between the deposited layer and low-k dielectric materials. Specifically, the heavy ions break the bonds within both the thin polymer layer and the bonds of the low-k dielectric materials to form a volatile reaction product that is desorbed from the surface. Profile control is achieved through a combination of an RF bias applied to the substrate platen, that causes the ions to bombard the base of the trench more than sidewalls of the feature, and the use of low processing pressure to reduce scattering. In accordance with a specific embodiment, a width 311 of the trench 355 can be approximately 80-100 micrometers, while a depth of the trench 355 is in the range of 30 micrometers to 400 micrometers, or more. In one embodiment, the depth is approximately 50 micrometers. The by forming the trench 355 at the scribe region 355, any structures present at level 112 within the scribe region 355 are destroyed during the etch process.

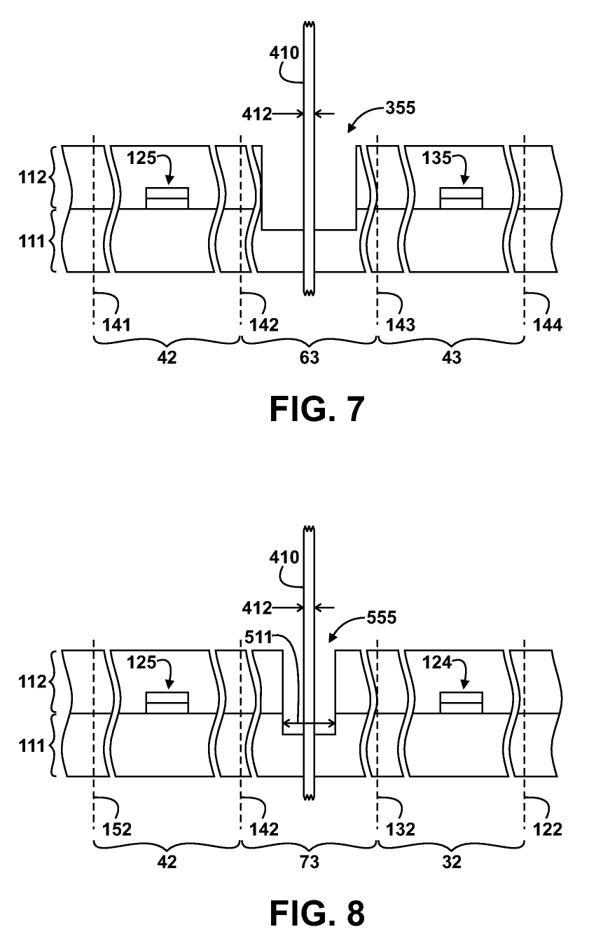

FIG. 6 includes an illustration of a portion of workpiece 10 of FIG. 5 while a saw blade 410, having a thickness 412 that less is than the thickness of the trench region 355, is being used to saw through the workpeice 10 within trench 355. The saw can include a diamond saw. FIG. 7 includes an illustration of the workpiece 10 of FIG. 6 after the saw blade 410 has been used to saw through the entire thickness of workpiece 10 as part of die singulation.

FIG. 8 includes a cross-sectional illustration of workpiece 10 along line 82 after formation of trench region 555 having a width 511 that is different than the width 311 of trench 355 illustrated at FIGS. 5-7. In accordance with a specific embodiment, orthogonal scribe lines of a workpiece can have varying widths. For example, vertical scribe lines of a semiconductor workpiece can have a different width than the workpiece's horizontal scribe lines. Similarly, the trench region 555, which can be a trench orthogonal to trench 355 of FIG. 7, can have a width that is different than trench 355. In one embodiment, trench 555 has a width that is narrower than the width of trench 355, even though the scribe line containing trench 255 563 can have the same width as the scribe line containing trench 555.7. Alternatively, trench 555 and the scribe line at which it is formed can both have widths narrower than trench 455 and the scribe line at which it is formed, respectively. As illustrated in FIGS. 7 and 8, blade 410 is used to cut both trench 455 and trench 555. This is an advantage over previous methods, where different blades having different thickness are used to make singulation cuts at thicker scribe regions than at thinner scribe regions, thereby necessitating the use of blades of multiple thicknesses to singulate a semiconductor workpiece.

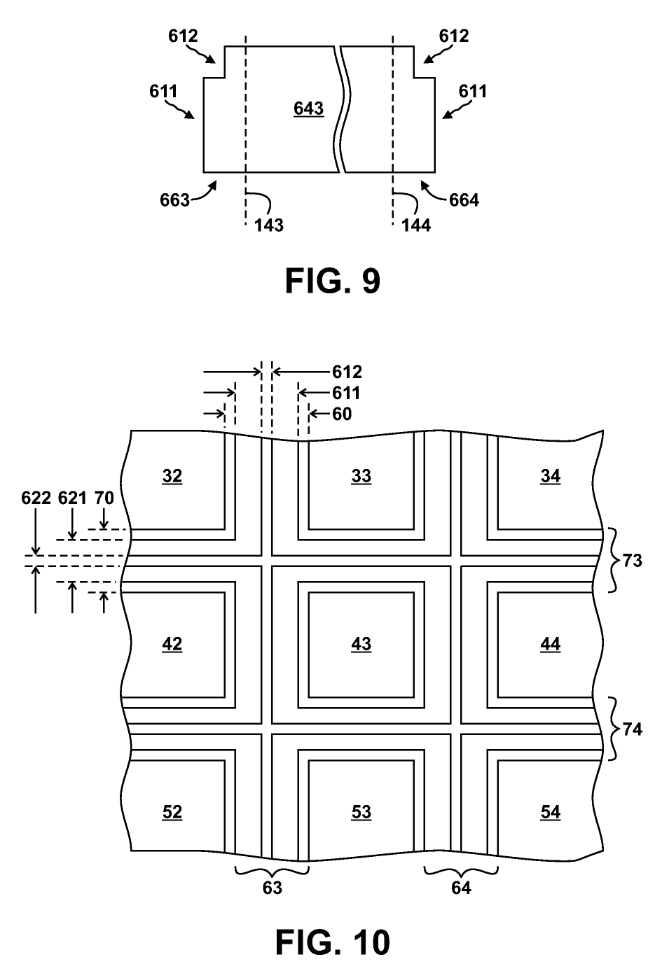

FIG. 9 illustrates a cross-sectional view of die 643 after being singulated from workpiece 10 at die location 43. The functional portion of die 643 resides between boundary lines 143 and 144. Portions 663 and 664 of FIG. 9 represent the remaining portions of scribe lines 63 and 64. A four-sided minor surface is formed between an upper and lower major surface of workpiece 10 of FIG. 9 after singulation. Each of the minor surfaces includes an outermost surface portion 611 and an innermost surface portion 612. The outermost surface portion is a sawed surface formed by the saw blade used to singulate die 643 from its workpiece. The innermost surface portion 612 is an etched surface formed by the etch process used to define trenches at which the blades are used.

FIG. 10 illustrates a plan view of the workpiece 10 indicating the location of additional features as described herein. Specific die locations are defined by the illustrated die locations 32-34, 42-44, and 52-54. Vertical scribe lines 63 and 64 between the illustrated die have a width 60, while the horizontal scribe lines 73 and 74 have a width 70 that is illustrated as smaller than width 60. In an alternate embodiment, the widths of scribe region 60 and 70 can be the same or the width 60 can be larger than width 60. The etch process within the scribe lines create vertical trench regions having width 611, which in one embodiment is larger than the width 621 of the horizontal trench regions formed at scribe lines 73 and 74. In an alternate embodiment, the widths of trench regions can have the same width or the width 611 can be smaller than width 621. The widths 612 and 622 represent the width and location where a mechanical cut is to be made, for example by saw 410, during singulation. Typically, the width of the saw used in the vertical and horizontal scribe regions will be the same. However, blades having different thicknesses can be used in the horizontal and vertical scribe lines.

Benefits, other advantages, and solutions to problems have been described above with regard to specific embodiments. However, the benefits, advantages, solutions to problems, and any element(s) that may cause any benefit, advantage, or solutions to occur or become more pronounced are not to be construed as a critical, required, or essential feature or element of any or all the claims. Accordingly, the present disclosure is not intended to cover such alternatives, modifications, and equivalents, as can be reasonably included within the spirit and scope of the disclosure.

What is claimed is:

1. Method comprising:
etching a trench at a first scribe region of a wafer comprising semiconductor devices; and
sawing the wafer within the trench.

2. The method of claim 1 wherein etching the trench further comprises etching through one or more active layers overlying a substrate at the first scribe region.

3. The method of claim 2 wherein the one or more active layers comprises a dielectric layer.

4. The method of claim 3 wherein the one or more active layers further comprises a conductive layer between the dielectric layer and the substrate.

5. The method of claim 3 wherein the one or more active layers further comprises a conductive layer, wherein the dielectric layer is between the conductive layer and the substrate.

6. The method of claim 3, wherein the dielectric layer is a back-end-of-line layer.

7. The method of claim 3, wherein the dielectric layer is a front-end-of-line layer.

8. The method of claim 2, wherein the first scribe region is between a first die comprising a semiconductor device and a second die comprising a semiconductor device.

9. The method of claim 1 wherein sawing further comprises sawing through the wafer within the trench to singulate dice defined by the first scribe region.

10. The method of claim 1, wherein etching further comprises etching the trench at a second scribe region, wherein the first scribe region has a length orthogonal to a length of the second scribe region.

11. The method of claim 10, wherein a width of the trench at the first scribe region is different than a width of the trench at the second scribe region.

12. The method of claim 11 wherein sawing the wafer further comprises sawing within the trench at the first scribe region and at the second scribe region using a common saw thickness.

13. The method of claim 11, wherein sawing the wafer further comprises sawing within the trench at the first scribe region and at the second scribe region using a common saw.

14. The method of claim 10, wherein a width of the trench at the first scribe region is the same than a width of the trench at the second scribe region.

15. The method of claim 1 wherein etching the trench further comprises the trench having a width of between 30 and 400 micro-meters.

16. The method of claim 1 further comprising:
forming a mask layer defining the first scribe region prior to etching.

17. The method of claim 16, wherein the mask layer is a photoresist mask.

18. The method of claim 1 wherein etching further comprises etching using a deep reactive ion etch.

19. The method of claim 1 wherein etching further comprises etching using a wet etch.

20. A device comprising:
a semiconductor device formed at a die, the die comprising a minor surface between a first major surface and a second major surface;
a first portion of the minor surface nearer the first major surface than the second major surface, the first portion comprising an etched surface; and
a second portion of the minor surface further from the first major surface than the first portion, the second portion comprising a sawed surface.

21. The device of claim 20, wherein a width of the die at the first major surface is less than a width of the die at the second major surface.
